(19) United States
(12) Patent Application Publication
(10) Pub. No.: US 2008/0113472 A1
(43) Pub. Date: May 15, 2008

(54) Film and chip packaging process using the same

(76) Inventors: Yueh Ming Tung, Fongshan City (TW); Kuo Yang Sun, Kaohsiung City (TW); Chia Ming Yang, Tainan city (TW); Hung Tai Mai, Yanchao Township (TW); Hui Chi Liu, Kaohsiung City (TW)

Correspondence Address: REED SMITH LLP, Suite 1400, 3110 Fairview Park Drive, Falls Church, VA, 22042, US

(21) Appl. No.: 11/979,792

(22) Filed: Nov. 8, 2007

(30) Foreign Application Priority Data
Nov. 9, 2006 (TW) 095141502

(51) Int. Cl. H01L 21/58; B32B 5/16; B32B 7/12

(52) U.S. Cl. 438/114; 428/343; 428/323; 257/E21.505

(57) ABSTRACT

A film includes a removable base material, a resin layer and a plurality of arc elastomers. The resin layer is a partially-cured resin which is in a half-melting state with viscosity at a temperature higher than a first temperature and in a solid state without viscosity at a temperature lower than a second temperature, and the resin layer in a solid state is adhered on the base material. The arc elastomers are disposed inside the resin layer. The present invention further provides a chip packaging process using the film.

### CROSS REFERENCE TO RELATED APPLICATION

This application claims the priority benefit of Taiwan Patent Application Serial Number 095141502, filed on Nov. 9, 2006, the full disclosure of which is incorporated herein by reference.

### BACKGROUND OF THE INVENTION

1. Field of the Invention

This invention generally relates to a film, and more particularly, to a film utilized in a chip packaging process.

2. Description of the Related Art

In a conventional chip stacking package, as shown in FIG. 1, the package includes a substrate 10, a lower chip 20, a dummy chip 30 and an upper chip 40. The lower chip 20 is mounted on the substrate 10 by means of an adhesive 22, and two side edges of the upper surface of the lower chip 20 are provided with a plurality of aluminum pads 24 which are electrically connected to a plurality of pads 12 of the substrate 10 through a plurality of first bonding wires 26. The dummy chip 30 is mounted on the lower chip 20 by means of an adhesive and defines the necessary space for the first bonding wires 26, such as greater than a height of 5 mils. The upper chip 40 is mounted on the dummy chip 30 by means of an adhesive 42 and the upper surface 48 of the upper chip 40 are provided with a plurality of aluminum pads 44 which are electrically connected to the pads 12 of the substrate 10 through a plurality of second bonding wires 46, such that the two chips 20, 40 are stacked on the substrate 10. However, this chip stacking package requires a higher manufacturing cost and longer packaging time. Furthermore, there is a mismatch between the expansion coefficients of the dummy chip and the adhesive, and thus the stress at the interface between the dummy chip and the adhesive is increased after an encapsulating process, thereby further resulting in chip crack and reducing the yield of the chip stacking package. The yield of the chip stacking package generally ranges between 30% and 40%.

In another chip stacking package, as shown in FIG. 2, the package includes a substrate 110, a first chip 120, an electrically nonconductive adhesive 130, a second chip 140 and a plurality of supporting balls 132. The first chip 120 has an upper surface and a lower surface opposite to the upper surface, and the lower surface is mounted on the substrate 110. The electrically nonconductive adhesive 130 is disposed on the upper surface of the first chip 120. The second chip 140 has an upper surface and a lower surface opposite to the upper surface, wherein the lower surface is mounted on the upper surface of the first chip 120 by means of the electrically nonconductive adhesive 130, and the plurality of supporting balls 132 are disposed inside the electrically nonconductive adhesive 130 for supporting the second chip 140. Although this kind of package can reduce the stress after an encapsulating process by means of increasing adhesive area between the electrically nonconductive adhesive and chips, eliminate chip crack and define the necessary space for bonding wires by means of the supporting balls 132, the electrically nonconductive adhesive 130 still has to be smeared over each chip every time before die attach. In this manner, not only the packaging time is increased but also the second chip 140 may tilt with respect to the surface on which it is mounted during die attach due to difficult control of the using quantity of the liquid electrically nonconductive adhesive 130.

In addition, in an alternative chip stacking package, which is disclosed in Taiwan Patent Number 1240392 and entitled “Process for packaging and stacking multiple chips with the same size”, a partially-cured resin is coated on a wafer, and then the wafer is cut to form a plurality of first chips. The partially-cured resin under one of the first chips is adhered to a substrate or the active surface of a second chip. A plurality of bonding wires are electrically connected the first chip with the substrate. During the stacking of the first and the second chips, the partially-cured resin between the chips is melted under heating to seal the ends of the wires. In this manner, more chips with the same size can be stacked in a limited package thickness. By using the partially-cured resin, the adhesive needs not to be smeared over chips every time before die attach so as to reduce packing time. However, since the partially-cured resin will be melted under heating, the necessary height between the first chip and the substrate (or the second chip) may not able to be maintained if the attaching force during die attach is too high. The first chip may contact with the bonding wires and thus reduce the yield of the chip stacking package.

According to the above reasons, it is necessary to further improve the chip stacking package so as to solve the problems existing in the related art.

### SUMMARY OF THE INVENTION

It is an object of the present invention to provide a film and a chip packaging process using the same, wherein the adhesive area between the film and the chip is increased so as to avoid stress increasing after an encapsulating process and further eliminate chip crack.

It is another object of the present invention to provide a film and a chip packaging process using the same, wherein a film disposed within a plurality of arc elastomers is utilized to support a chip so as to define a necessary space for bonding wires or mounting passive components.

It is a further object of the present invention to provide a film and a chip packaging process using the same, which can decrease packaging time by adhering a film on the back surface of a chip rather than smearing adhesive thereon every time before die attach.

It is a further object of the present invention to provide a film and a chip packaging process using the same, wherein the film has a constant volume and height such that the difficult control problem of the height of the chip during die attach can be overcome so as to increase the manufacturing yields.

In order to achieve the above objects, the film according to the present invention includes a removable base material, a resin layer and a plurality of arc elastomers. The resin layer is a partially-cured resin which is in a half-melting state with viscosity at a temperature higher than a first temperature and in a solid state without viscosity at a temperature lower than a second temperature, and the resin layer in a solid state is adhered on the base material. The arc elastomers are disposed inside the resin layer.

The present invention further provides a chip packaging process, which utilizes a film formed by combining a resin layer in a solid state and a base material as an adhesive material for chips and a plurality of arc elastomers are disposed inside the resin layer. The chip packaging process includes: providing a wafer having an active surface and a back surface opposite to the active surface, wherein a plurality of pads are formed on the active surface; adhering the film on the back surface of the wafer; cutting the wafer into a plurality of chips; removing the base material of the film adhered on the back surface of a chip, called first chip; and adhering the first chip to a carrier through the resin layer adhered thereon; thereby a predetermined space between the first chip and the carrier can be defined by means of the arc elastomers.

According to the present invention, the first balls are all circular or classified into circular and oval shape; the shapes of the second balls are not limited to a specific shape since the second balls are for separating the first balls.

### BRIEF DESCRIPTION OF THE DRAWINGS

Other objects, advantages, and novel features of the present invention will become more apparent from the following detailed description when taken in conjunction with the accompanying drawings.

FIG. 1 shows a conventional chip stacking package.

FIG. 2 shows conventional chip stacking package.

FIG. 3a shows a schematic diagram of a film according to the first embodiment of the present invention.

FIG. 3b shows a schematic diagram of a film according to the second embodiment of the present invention.

FIG. 3c shows a schematic diagram of a film according to the third embodiment of the present invention.

FIG. 4 shows a flow chart of a chip packaging process utilizing the film according to the embodiments of the present invention.

FIG. 5a to 5f show cross-sectional schematic views of a chip packaging process utilizing the film according to the embodiments of the present invention, wherein the carrier is a substrate.

FIG. 6a to 6b show cross-sectional schematic views of another chip packaging process utilizing the film according to the embodiments of the present invention, wherein the carrier is a chip.

### DETAILED DESCRIPTION OF THE PREFERRED EMBODIMENT

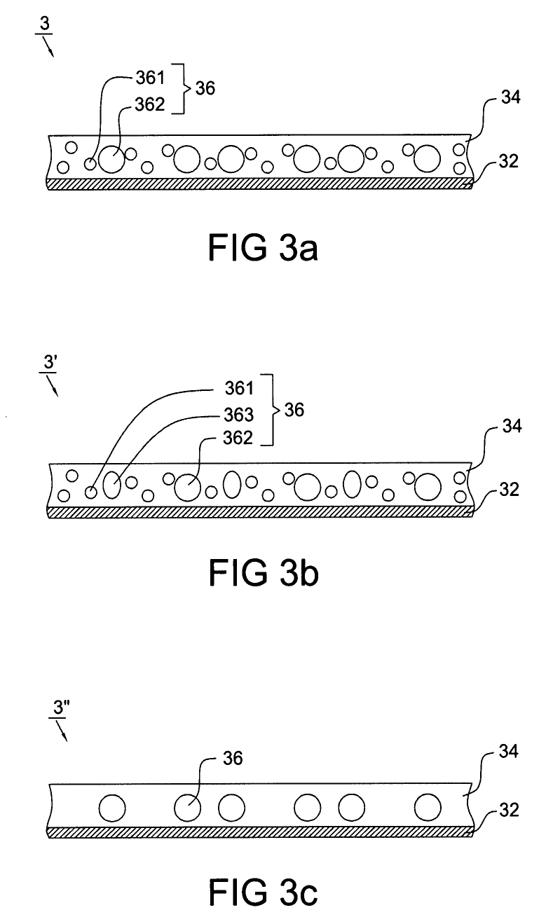

Referring to FIG. 3a, it shows a film 3 according to the first embodiment of the present invention. The film 3 includes a removable base material 32, a resin layer 34 and a plurality of arc elastomers 36 disposed inside the resin layer 34. The film 3 can be utilized in a chip packaging process as an adhesive material for chips. Embodiments of the base material 32 include a BT substrate and a tape. When the base material 32 is a BT substrate, it can be combined to the resin layer 34 by means of an epoxy; on the other hand, when the base material 32 is a tape, e.g. a flexible tape, a UV tape or a blue tape, it can be directly attached to the resin layer 34. A resin layer 34 in the solid state interfused within the arc elastomers 36 is adhered to the base material 32. In order to be adapted to chip packaging processes, the base material 32 preferably can endure at least a temperature of 85 degrees centigrade.

One embodiment of the resin layer 34 is a partially-cured resin, e.g. a resin composed of epoxy resin and phenol resin, which is preferable in a solid state without viscosity at room temperature, e.g. below 45 degrees centigrade, and in a half-melting state with viscosity at high temperatures, e.g. above 85 degrees centigrade. The arc elastomers 36 are preferably made of heat-resistant material, e.g. rubber, and are classified into first balls 362 and second balls 361, and a diameter of the first balls 362 is larger than that of the second balls 361. The second balls 361 are for separating the first balls 362 and a number of the second balls 362 is preferably less than 20% of that of all arc elastomers 36. In addition, the shapes of the second balls 361 are not limited to circular and they may be any shapes, for example oval shape. Since the first balls 362 are utilized to define a height for bonding wires or mounting passive components in chip packaging processes, a diameter of the first balls 362 is preferably at least from 3 to 8 mils (1 mil=25.4 micrometers). In this embodiment, the thickness of the resin layer 34 is larger than the diameter of the first balls 362, e.g. preferably by 4 to 10 micrometers, such that a distance can be formed between the arc elastomers 36 and the surfaces of the resin layer 34, and the arc elastomers 36 can freely move and be rearranged uniformly in the resin layer 34 after the resin layer 34 is heated to half-melting state. The resin layer 34 and the arc elastomers 36 are preferably made of nonconductive material.

Referring to FIG. 3b, it illustrates a film 3′ according to the second embodiment of the present invention. The elements in this embodiment which are identical to those shown in the first embodiment are indicated by the same reference numerals. The differences between the second embodiment and the first embodiment are that, besides the first balls 362 and the second balls 361, the arc elastomers 36 further include a plurality of spheroids 363. A length of the long axis of the spheroids 363 is preferably equal to a diameter of the first balls 362 and the corresponding detailed descriptions of its function will be illustrated in the following paragraphs. A thickness of the resin layer 34 is also larger than a diameter of the first balls 362, e.g. preferably by 4 to 10 micrometers. The arc elastomers 36 are also made from heat-resistant material such as rubber. In this embodiment, the resin layer 34 and the arc elastomers 36 are also made from nonconductive material.

Referring to FIG. 3c, it depicts a film 3″ according to the third embodiment of the present invention. In this embodiment, the elements which are identical to those shown in the first embodiment are also indicated by the same reference numerals. The differences between this embodiment and the first and the second embodiments are that, the arc elastomers 36 are spheres with identical diameters, e.g. the first balls 362 in the first and the second embodiments. The arc elastomers 36 are also utilized for defining a predetermined height for bonding wires or passive components in a chip packaging process; therefore, a diameter of the arc elastomers 36 is at least from 3 to 8 mils. In this embodiment, a thickness of the resin layer 34 is also larger than a diameter of the arc elastomers 36 by 4 to 10 micrometers. The arc elastomers 36 are also preferably made of heat-resistant material, e.g. rubber, and the resin layer 34 and the arc elastomers 34 are also made of nonconductive material.

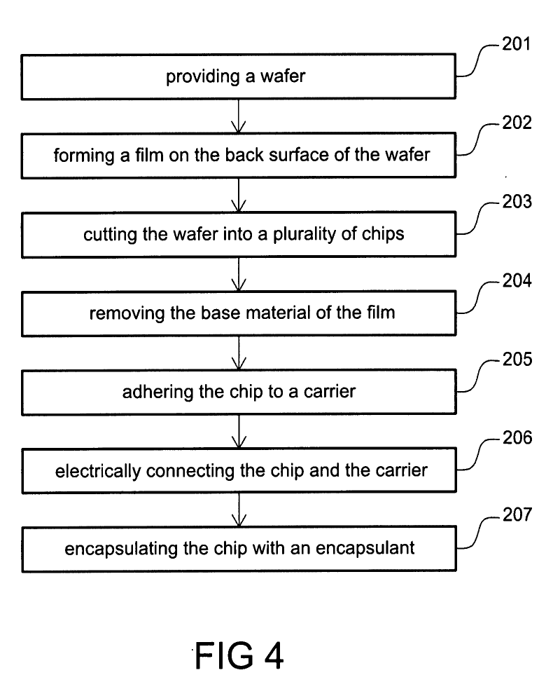

Referring to FIGS. 4, 5a to 5f and 6a to 6b, they respectively illustrate a flow chart and cross-sectional schematic views of a chip packaging process utilizing the films 3, 3′ and 3″ according to the embodiments of the present invention, wherein the films 3, 3′ and 3″ are served as an adhesive material for chips. The chip packaging process has the following steps: providing a wafer having an active surface and a back surface opposite to the active surface, wherein a plurality of pads are provided on the active surface (step 201); forming the film on the back surface of the wafer (step 202); cutting the wafer into a plurality of chips, wherein the back surface of each chip is adhered with the film (step 203); removing the base material of the film adhered on the back surface of a first chip, called first chip (step 204); adhering the first chip to a carrier through the resin layer adhered thereon (step 205), thereby a predetermined space between the first chip and the carrier can be defined by means of the arc elastomers; electrically connecting the first chip and the carrier (step 206) and encapsulating the first chip by means of an encapsulant (step 207). In addition, it should be noted that identical elements shown in figures are indicated by the same reference numerals.

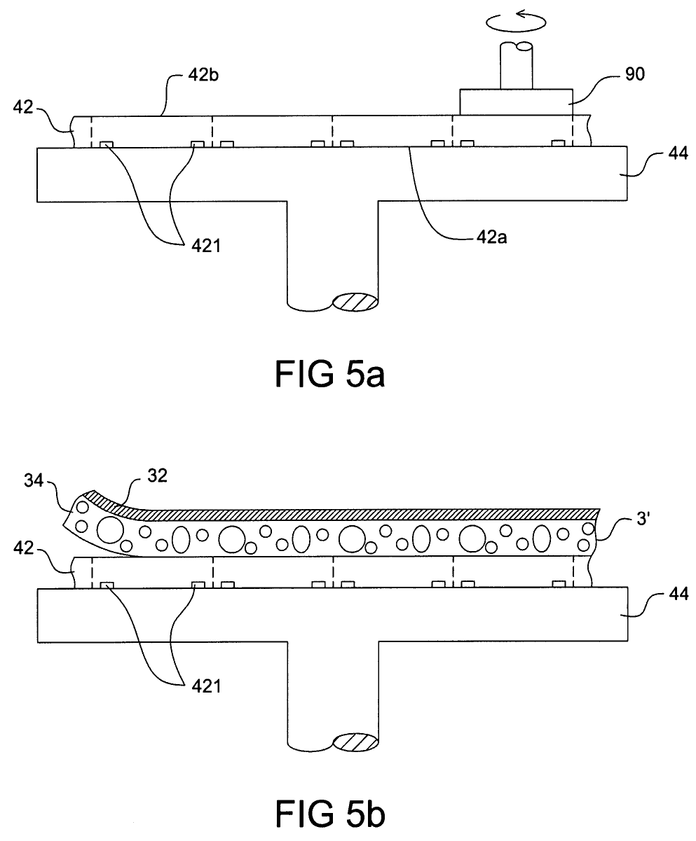

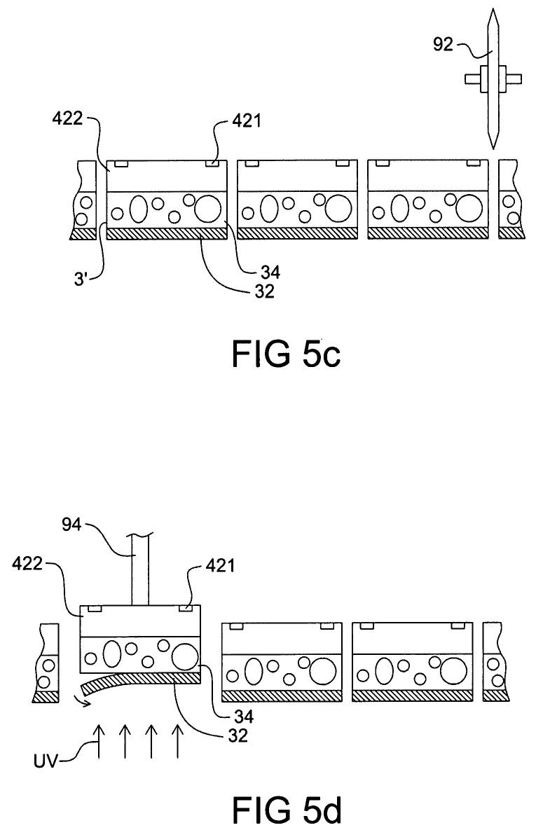

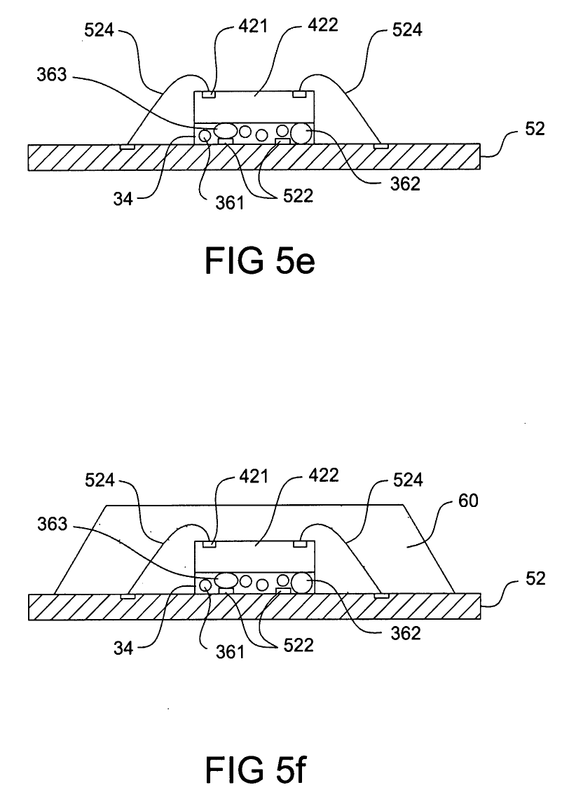

Referring to FIGS. 4 and 5a, in the chip packaging process according to the present invention, the first step is to provide a wafer 42 which has an active surface 42a and a back surface 42b opposite to the active surface 42a, and a plurality of pads 421 are provided on the active surface 42a (step 201). Then, the wafer 42 is placed on a wafer carrier 44 through its active surface 42a. A wafer grinding machine 90 is utilized to grind the back surface 42b of the wafer 42 to a predetermined thickness, e.g. normally more than 1 mil.

Referring to FIGS. 4 and 5b, after the wafer 42 is ground to the predetermined thickness, then the film 3′ according to the second embodiment of the present invention is adhered to the back surface 42b of the wafer 42 (step 202). In should be noted that, in the descriptions corresponding to FIGS. 5a to 5f, the film 3′ of the second embodiment is served as an example to describe the chip packaging process of the present invention. The chip packaging processes use the films 3 and 3″ as adhesive material are similar to the process utilizes the film 3′; therefore, the corresponding detailed descriptions will not be illustrated herein. As mentioned above, because the film 3′ is in a solid state at room temperature (below 45 degrees centigrade), it has to be disposed into a curing oven (not shown) or the like to be heated to a high temperature (above 85 degrees centigrade) so as to be changed to a half-melting state with viscosity. Therefore, the film 3′ has to be heated before being adhered to the wafer 42. However, in order not to overreact the film 3′, the heating time should be controlled as a time that the film 3′ appears half-melting state and is able to be adhered to the wafer 42, e.g. 2 seconds.

Referring to FIGS. 4 and 5c, then a dicing blade 92 is utilized to cut the wafer 42 so as to form a plurality of chips, wherein one of the chips is assumed to be a first chip 422. The back surface of each chip, including the first chip 422, is adhered with the film 3′ and the active surface of each chip has a plurality of pads 421 formed thereon (step 203). Embodiments of the plurality of chips include dynamic random access memories (DRAM), static random access memories (SRAM), flash memories (FLASH), double data rate memories (DDR), Rambus memories, microprocessors, logic chips or radio chips etc.

Referring to FIGS. 4 and 5d, before the first chip 422 is mounted on a carrier, the base material 32 of the film 3′ has to be removed first (step 204). If the base material 32 is a UV tape, it has to be lighted by UV light and then can be removed. If the base material 32 is a flexible tape, a blue tape or a BT substrate, it can be removed directly. And then the first chip 422 is mounted on a predetermined carrier 52 by means of an automatic selecting and setting apparatus 94.

Referring to FIG. 5e, the first chip 422 is then mounted on a carrier 52 through the film 3′ (step 205). In the embodiment of the present invention, the carrier 52 can be a substrate, a lead frame or a chip (a second chip). In order to have the first chip 422 to be adhered to the carrier 52 through the resin layer 34, the first chip 422 has to be heated to a relatively high temperature for a short period of time, e.g. higher than 85 degrees centigrade for 2 seconds, such that the first chip 422 can be pre-adhered to the carrier 52. If the carrier 52 is a substrate, it is preferably to use the film 3′ of the second embodiment as an adhesive material for the adhesion of the first chip 422, wherein the arc elastomers 36 are classified into a plurality of first balls 362, second balls 361 and spheroids 363 and the first balls 362 and the spheroids 363 are separated by the second balls 361. When the resin layer 34 is adhered to the carrier 52, due to the resin layer 34 appearing half-melting state after being heated, the first balls 362 and the spheroids 363 disposed therein can freely move to dodge components 522 disposed on the carrier 52, e.g. passive components. Then a necessary height for the components 522 can be defined by means of the first balls 362. If the spheroids 363 are just right above the components 522, they can rotate due to their arc shape, as shown in FIG. 5e, such that the first chip 422 can be flatly mounted on the carrier 52. Therefore, even though the attaching force during die attach is too high, the flatness still can be maintained from the existence of the first balls 362. And then the pads 421 on the first chip 422 are connected to the carrier 52 through a plurality of first bonding wires 524 (step 206).

Referring to FIG. 5f, finally an encapsulant 60 is utilized to encapsulate the first chip 422 and the first bonding wires 524, and the whole package is placed into a curing oven or the like to be heated for a relatively longer period of time, e.g. above 85 degrees centigrade for 120 seconds. In this manner, the resin layer 34 which is pre-adhered to the carrier 52 can be completely reacted through this heating step and the chip packaging process is completed (step 207).

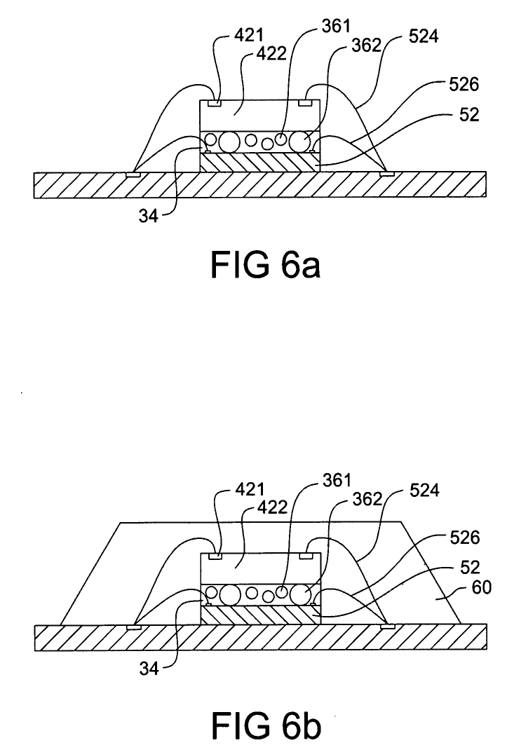

Referring to FIG. 6a, if the carrier 52 is a chip (a second chip), generally a plurality of second bonding wires 526 are connected thereto and the chip is mounted on a substrate or a lead frame. In this exemplary packaging process, the film 3 of the first embodiment can be utilized as an adhesive material for the adhesion of the first chip 422, wherein the arc elastomers 36 include a plurality of first balls 362 and second balls 361, and the first balls 362 are separated by the second balls 361. When the resin layer 34 is adhered to the carrier 52, due to the resin layer 34 appearing half-melting state after being heated, the first balls 362 disposed therein can freely move to dodge the second bonding wires 526. Then a necessary height for the second bonding wires 526 can be defined by means of the first balls 362. Therefore, even though the attaching force during die attach is too large, the flatness still can be maintained from the existence of the first balls 362. And then the pads 421 on the first chip 422 are electrically connected to the substrate or the lead frame on which the second chip mounted through the first bonding wires 524 (step 206). In addition, when the carrier 52 is a chip, the films 3′ and 3″ still can be utilized as an adhesive material for the adhesion of the first chip 422.

Referring to FIG. 6b, finally an encapsulant 60 is utilized to encapsulate the first chip 422, the first bonding wires 524, the carrier 52 and the second bonding wires 526, and then the whole package is placed into a curing oven (not shown) or the like to be heated for a relatively longer period of time, e.g. above 85 degrees centigrade for 120 seconds. In this manner, the resin layer 34 which is pre-adhered to the carrier 52 can be completely reacted through this heating step and the chip packaging process is accomplished (step 207).

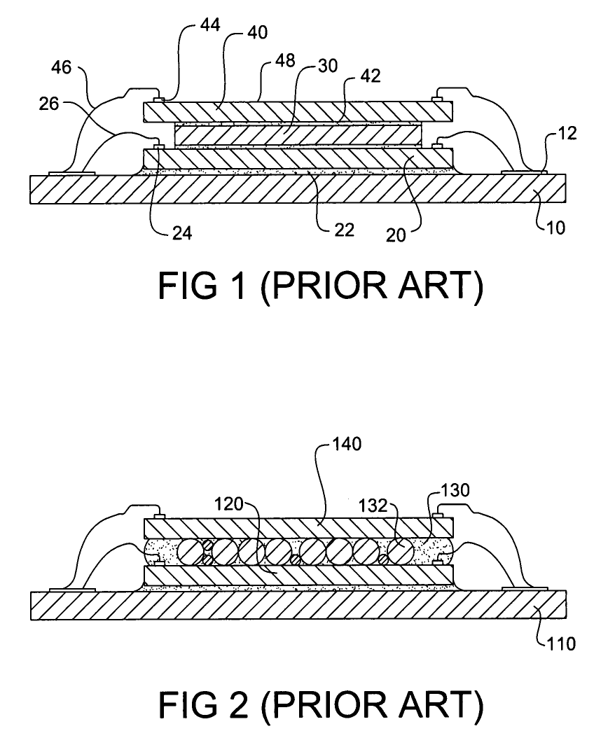

As described above, the conventional chip stacking package shown in FIG. 1 has the problems of die crack and long packaging time; the package shown in FIG. 2 has the problem of the using quantity of the adhesive is difficult to be controlled such that tilt of the chip may happen during die attach. Compared with the conventional chip stacking package shown in FIGS. 1 and 2, the films according to the embodiments of the present invention as shown in FIGS. 3a to 3c are utilized to support a chip and to define a necessary space for bonding wires and/or passive components by means of disposing a plurality of arc elastomers therein. In this manner, the packaging time can also be decreased.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. A film, comprising:
a removable base material;
a resin layer in a solid state adhered on the base material, wherein the resin layer is a partially-cured resin which is in a half-melting state with viscosity at a temperature higher than a first temperature and in a solid state without viscosity at a temperature lower than a second temperature; and
a plurality of arc elastomers disposed inside the resin layer.

2. The film as claimed in claim 1, wherein the base material is selected from a group consisting of a BT substrate, a tape, a flexible tape, a UV tape and a blue tape.

3. The film as claimed in claim 1, wherein the first temperature is 85 degree centigrade, and the second temperature is 45 degree centigrade.

4. The film as claimed in claim 1, wherein the arc elastomers comprise first balls and second balls and a diameter of the first balls is larger than that of the second balls.

5. The film as claimed in claim 4, wherein the resin layer has a predetermined thickness which is larger than the diameter of the first balls such that a distance can be formed between the surfaces of the resin layer and the first and second balls.

6. The film as claimed in claim 5, wherein a number of the second balls is less than 20% of that of all arc elastomers.

7. The film as claimed in claim 6, wherein the first and second balls are selected from a group consisting of circular and oval shape.

8. The film as claimed in claim 6, wherein the first balls comprise circular and oval shape.

9. The film as claimed in claim 3, wherein the arc elastomers are made of heat-resistant material.

10. The film as claimed in claim 1, wherein the arc elastomers and the resin layer are made of nonconductive material.

11. The film as claimed in claim 1, wherein the arc elastomers are spheres with identical diameters.

12. A chip packaging process, utilizing a film formed by combining a resin layer in a solid state and a base material as an adhesive material for chips, wherein the resin layer is a partially-cured resin which is in a half-melting state with viscosity at a temperature higher than a first temperature and in a solid state without viscosity at a temperature lower than a second temperature, and a plurality of arc elastomers are disposed inside the resin layer, the chip packaging process comprising the steps of:
providing a wafer having an active surface and a back surface opposite to the active surface, wherein a plurality of pads are formed on the active surface;
adhering the film on the back surface of the wafer;
cutting the wafer into a plurality of chips;
removing the base material of the film adhered on the back surface of a chip, called first chip; and
adhering the first chip to a carrier through the resin layer adhered thereon;
whereby defining a predetermined space between the first chip and the carrier by means of the arc elastomers.

13. The chip packaging process as claimed in claim 12, wherein in the step of providing a wafer, the wafer is pre-ground to a predetermined thickness.

14. The chip packaging process as claimed in claim 12, wherein in the step of adhering the film on the back surface of the wafer further comprises a step of: heating the film to a temperature higher than a first temperature so as to attach the film to the back surface of the wafer, and before the step of adhering the first chip to the carrier further comprises a step of: heating the film to a temperature higher than a first temperature.

15. The chip packaging process as claimed in claim 12, wherein the carrier is selected from a group consisting of a substrate, a lead frame and a second chip.

16. The chip packaging process as claimed in claim 12, wherein the arc elastomers comprise first balls and second balls and a diameter of the first balls is larger than that of the second balls; the first balls have a predetermined diameter so as to define the necessary space between the first chip and the carrier.

17. The chip packaging process as claimed in claim 16, wherein the carrier is selected from a group consisting of a substrate, a lead frame and a second chip.

18. The chip packaging process as claimed in claim 17, wherein the necessary space between the first chip and the carrier is provided for bonding wire or mounting passive components.

19. The chip packaging process as claimed in claim 16, wherein the first and second balls are selected from a group consisting of circular and oval shape.

20. The chip packaging process as claimed in claim 16, wherein the first balls comprise circular and oval shape.
